(19) United States
(12) Patent Application Publication
(10) Pub. No.: US 2026/0282986 A1
(43) Pub. Date: Sep. 17, 2026

(54) SYSTEM INCLUDING AT LEAST TWO DIFFERENT TYPES OF FLEXURES

(71) Applicant: CANON KABUSHIKI KAISHA, Tokyo (JP)

(72) Inventors: Nilabh K. ROY, Cedar Park, TX (US); Anshuman Cherala, Austin, TX (US)

(21) Appl. No.: 19/077,888

(22) Filed: Mar. 12, 2025

(51) Int. Cl. H01L 23/00

(52) U.S. Cl. CPC H10W 72/011; H10W 99/00; H10W 72/071; H10W 80/168; H10W 80/312; H10W 80/327

(57) ABSTRACT

A system can include different types of flexures. In a non-limiting implementation, one of the flexures can include a guiding flexure, and another flexure can include a decoupling flexure. The guiding flexure can allow translation of a movable object in a desired direction. The decoupling flexure can help to reduce movement in undesired directions and rotational movement. In the same or different implementation, an actuator system can include an actuator that is coupled to the flexures. The actuator system can be incorporated as a sub-assembly into a larger system. In an implementation, the larger system may be a die bonding system. A method of using the die bonding system can allow for the position of a movable platform to allow for more precise positioning of a die to a die bonding site of a bonding substrate.

### FIELD OF THE DISCLOSURE

The present disclosure relates to a system including at least two different types of flexures.

### RELATED ART

Axial actuators are designed to perform linear motion, supply a force along a single axis, or both. Transverse motion at the actuator can degrade the performance of the actuator and subsequently the bandwidth, force output, linearity, and stability. Bandwidth refers to the response rate of the axial actuators to requested changes in the desired motion, force supplied by the actuator, or both the changes in desired motion and force supplied by the actuator. A lower bandwidth results in lower equipment throughput. Force output of the axial actuators could be degraded by the transverse motion or force on the actuators leading to changing current versus force relationships in the intended motion direction of the actuators, which has an impact on linearity and repeatability of the motion of the bonding system. Linearity refers to the ability to travel along the central axis of the axial actuator. As linearity becomes worse, the distal end of the moving portion may not be able to stay within tolerance when the moving portion is extended from the body of the actuator. Stability and robustness of a multi-degree of freedom motion system with high bandwidth in closed loop control is also affected by suitable isolation of the axial actuators from the motion of the moving platform. A need exists for a system that allows movement in a linear drive direction that has acceptable bandwidth, force output, linearity, and stability characteristics.

### SUMMARY

In a first aspect, a die bonding system can include a first frame; a first movable platform adapted to retain a first die chuck; and a first actuator for moving the first movable platform relative to the first frame. The first actuator can include a first fixed portion attached to the first frame, and a first moving portion that is adapted to supply a first force in a first direction relative to the first fixed portion. The die bonding system can further include a first flexure with a first degree of freedom in the first direction and is connected to the first moving portion of the first actuator and the first frame, and a second flexure with a plurality of degrees of freedom in directions other than the first direction and is connected to the first moving portion of the first actuator and the first movable platform.

In an implementation, the first degree of freedom of the first flexure is an only degree of freedom for the first flexure, and the second flexure has five degrees of freedom.

In another implementation, the first flexure includes a parallelogram, one double parallelogram, or a plurality of parallelograms, and the second flexure is a wire flexure.

In a particular implementation, the first flexure includes the one double parallelogram and no other double parallelogram.

In another particular implementation, the wire flexure includes a midsection, a first end section along a first end of the midsection, and a second end section along a second end of the midsection that is opposite the first end of the midsection, wherein a diameter of the midsection is greater than a diameter of each of the first end section and the second end section.

In a further implementation, the first flexure includes a base connected to the first frame, a first flexure moving portion connected to the first moving portion of the first actuator, an intermediate body, a first blade connecting the base to the intermediate body, and a second blade connecting the first flexure moving portion to the intermediate body. The second flexure passes through the first blade and the second blade of the first flexure without touching the first blade or the second blade.

In a particular implementation, the first blade is adapted such that the second flexure passes through a center of compliance of the first flexure.

In another particular implementation, the second flexure includes a wire flexure that includes a midsection, a first end section along a first end of the midsection, and a second end section along a second end of the midsection that is opposite the first end of the midsection. A diameter of the midsection is greater than a diameter of each of the first end section and the second end section. The midsection extends through the first blade and the second blade.

In another implementation, the second flexure is adapted to be coupled between the first flexure and the first die chuck.

In still another implementation, the first actuator includes a voice coil actuator, a piezoelectric actuator, a stepper motor, a servo motor, or a thermal expansion actuator.

In a further implementation, a first die bonding head includes the first movable platform, the first actuator, the first flexure, and the second flexure, and the die bonding system further includes a second die bonding head that is substantially identical to the first die bonding head.

In another implementation, the die bonding system further includes a second frame, a second movable platform adapted to retain a second die chuck, wherein the second movable platform is spaced apart from the first movable platform, and a second actuator for moving the second movable platform relative to the second frame. The second actuator includes a second fixed portion attached to the second frame, and a moving portion that adapted to supply a second force in the first direction relative to the second fixed portion. The die bonding system further includes a third flexure including a double parallelogram, wherein the double parallelogram is an only double parallelogram of the third flexure, wherein the third flexure is connected to the moving portion of the second actuator and the second frame, and a fourth flexure is connected to the third flexure and the second movable platform, wherein the fourth flexure is a wire flexure.

In a further implementation, the die bonding system further includes a second frame, a second movable platform adapted to retain a second die chuck, wherein the second movable platform is spaced apart from the first movable platform, and a second actuator for moving the second movable platform relative to the second frame. The second actuator includes a second fixed portion attached to the second frame, and a moving portion that adapted to supply a second force in the first direction relative to the second fixed portion. The die bonding system further includes a third flexure including a first blade and a second blade, wherein the third flexure is connected to the moving portion of the second actuator and the second frame, and a fourth flexure extending through the first blade and the second blade of the third flexure without touching the first blade and the second blade and is connected to the third flexure and the second movable platform.

In another aspect, a system can include a first flexure including a double parallelogram and adapted to be connected to a frame, wherein the double parallelogram is an only double parallelogram of the first flexure; and a second flexure is coupled to the first flexure, wherein the second flexure is a wire flexure.

In an implementation, the system further includes an actuator including a moving portion coupled to the first flexure, wherein the second flexure is adapted to be coupled to a movable object.

In a particular implementation, the second flexure is adapted to be coupled between the first flexure and the movable object.

In another implementation, the first flexure is a guiding flexure, and the second flexure is a decoupling flexure.

In still another aspect, a system can include a first flexure including a first blade, and a second flexure coupled to the first flexure and extending through the first blade without touching the first blade.

In an implementation, the first flexure includes a plurality of blades including the first blade and a second blade, and the second flexure extends through the second blade without touching the second blade.

In another implementation, the system further includes an actuator including a moving portion coupled to the first flexure, wherein the second flexure is adapted to be coupled to a movable object.

In a further aspect, a method of manufacturing a plurality of articles can include bonding a die to a substrate using a die bonding system. The die bonding system can include a first frame; a first movable platform adapted to retain a first die chuck; a first actuator for moving the first movable platform relative to the first frame. The first actuator can include a first fixed portion attached to the first frame; and a first moving portion that is adapted to supply a first force in a first direction relative to the first fixed portion. The die bonding system can further include a first flexure with a first degree of freedom in the first direction and is connected to the first moving portion of the first actuator and the first frame; and a second flexure with a plurality of degrees of freedom in directions other than the first direction and is connected to the first moving portion of the first actuator and the first movable platform. The method can further include processing the substrate to manufacture the plurality of articles.

### BRIEF DESCRIPTION OF THE DRAWINGS

Implementations are illustrated by way of example and are not limited in the accompanying figures.

FIG. 1 includes a conceptual view of an actuator system that includes different types of flexures.

FIG. 2 includes a side view of a flexure that includes a parallelogram-based structure having a parallelogram that is not a double parallelogram.

FIG. 3 includes a side view of the flexure of FIG. 2 when a force is applied in a Z-direction.

FIG. 4 includes a side view of a flexure that includes a parallelogram-based structure having one double parallelogram.

FIG. 5 includes a side view of the flexure of FIG. 4 when a force is applied in a Z-direction.

FIG. 6 includes a side view of a flexure that includes a parallelogram-based structure having a plurality of double parallelograms.

FIG. 7 includes a perspective view of a flexure that includes a parallelogram-based structure having one double parallelogram.

FIG. 8 includes a bottom view of the flexure of FIG. 7.

FIG. 9 includes a side view of the flexure of FIG. 7.

FIG. 10 includes a conceptual view of a wire flexure that include a midsection with a larger diameter as compared to end sections that are along opposite ends of the midsection.

FIG. 11 includes a perspective view of a wire flexure that includes a midsection, end sections, and mounting plates.

FIG. 12 includes a side view of the flexure of FIG. 11.

FIG. 13 includes a bottom view of the flexure of FIG. 11.

FIG. 14 includes a perspective view of an actuator coupled to the wire flexure of FIGS. 11 to 13.

FIG. 15 includes a perspective view of an actuator system that include the actuator and wire flexure in FIG. 14 and the flexure of FIGS. 7 to 9 coupled to the wire flexure.

FIG. 16 includes a perspective view of the actuator system of FIG. 15, wherein the perspective view in FIG. 16 is from a different view angle as compared to FIG. 15.

FIG. 17 includes a perspective view of a lower frame member.

FIG. 18A includes a perspective view of a portion of a module that includes the lower frame member and further includes a movable platform, a die chuck holder, and a die chuck.

FIG. 18B includes a perspective view of the portion of the module in FIG. 18A from a different view angle.

FIG. 19 includes the portion of the module of FIGS. 18A and 18B with actuator systems coupled to a top surface of the movable platform.

FIG. 20 includes the portion of the module of FIG. 19 with other actuator systems coupled to tabs of the movable platform.

FIG. 21 includes a perspective view of an internal frame member.

FIG. 22 includes a bottom view of the internal frame member of FIG. 21.

FIG. 23 includes an illustration of the portion of the module of FIG. 20 and the internal frame member of FIGS. 21 and 22, wherein the internal frame member is coupled to components within the portion of the module.

FIG. 24 includes a perspective view of an upper frame member and position sensors.

FIG. 25 includes a perspective view of the module that includes the portion of the module in FIG. 23 and the upper frame member and the position sensors in FIG. 24.

FIG. 26 include a conceptual view of a die bonding system that can be used to bond dies to die bonding sites of a bonding substrate, wherein the die bonding system includes the module of FIG. 25.

FIG. 27 includes a process flow diagram for a method of bonding dies to bonding sites of the bonding substrate using the die bonding system of FIG. 26.

FIG. 28 includes a process flow diagram for a more detailed portion of the method in FIG. 27.

FIG. 29 includes an illustration of a side view of the die bonding system of FIG. 26 and further includes a set of dies coupled to an array of bonding heads and a bonding substrate coupled to a bonding substrate chuck, wherein the set of dies are positioned over registration hardware.

FIG. 30 includes an illustration of a cross-sectional view of a die chuck and a particular die from the set of dies in FIG. 29 before the particular die is bowed.

FIG. 31 includes an illustration of a side view of the die bonding system, the set of dies, and the bonding substrate of FIG. 29 after moving the set of dies over their corresponding die bonding sites of the bonding substrate.

FIG. 32 includes an illustration of a cross-sectional view of a die chuck and the particular die in FIG. 31 during a time when the particular die is bowed.

FIG. 33 includes an illustration of a cross-sectional view of the die chuck, the particular die in FIG. 32 and a bonding substrate when the particular die initially contacts a die bonding site of the bonding substrate.

FIG. 34 includes an illustration of a cross-sectional view of the die chuck, the particular die, and the bonding substrate of FIG. 33 when the particular die is bonded to the die bonding site of the bonding substrate.

FIG. 35 includes an illustration of a side view of the die bonding system, the set of dies, and the bonding substrate after the die chucks of the array of bonding heads are no longer coupled to the set of dies.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the inventive concepts.

### DETAILED DESCRIPTION

The following description in combination with the figures is provided to assist in understanding the teachings disclosed herein. The following discussion will focus on specific implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

A system can include different types of flexures. In a non-limiting implementation, one of the flexures can include a guiding flexure, and another flexure can include a decoupling flexure. The guiding flexure can allow translation of a movable object in a desired direction. An example of the guiding flexure can be a parallelogram-based flexure. The decoupling flexure can help to reduce movement in undesired directions and rotational movement. An example of the decoupling flexure can include a wire flexure. In a particular implementation, one of the flexures, for example, the wire flexure, can pass through another flexure, for example, the guiding flexure, and help to reduce the space occupied by the flexures.

In the same or different implementation, an actuator system can include an actuator that is coupled to the flexures. The actuator system can be incorporated as a sub-assembly into a larger system. In an implementation, the larger system may be a module within a die bonding head of a die bonding system. A method of using the die bonding system can allow for the positioning of a movable platform to allow for more precise positioning of a die to a die bonding site of a bonding substrate when the die is bonded to its corresponding die bonding site.

Implementations described below are exemplary and do not limit the scope of the inventive concepts. While some die chucks will be described mostly with respect to an array of bonding heads, and other die chucks will be described mostly with respect to an array of die transfer seats, the die chucks for the array of bonding heads may be used for the array of die transfer seats, and the die chucks for the array of die transfer seats may be used for the array of bonding heads.

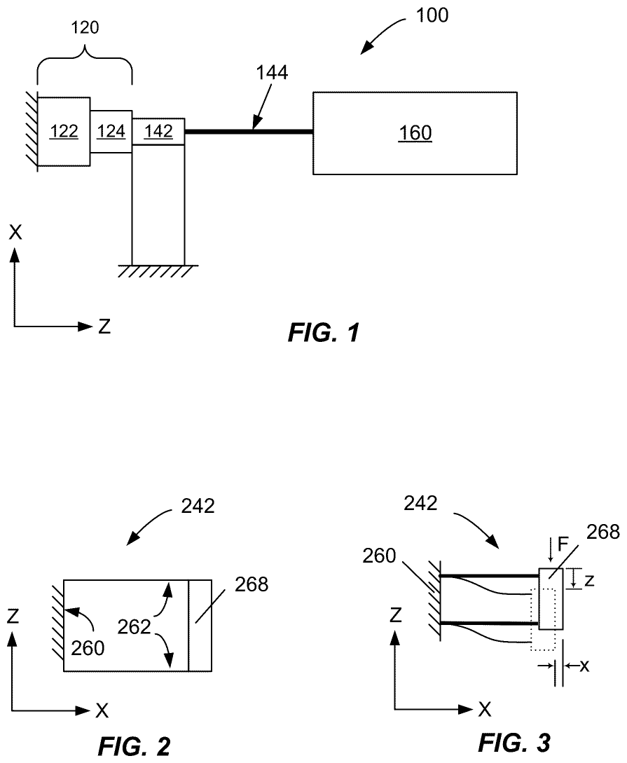

FIG. 1 includes a conceptual view of a system 100 that can be used in a linear drive application. In the implementation illustrated, the system 100 is an actuator system. The system 100 can include an actuator 120 that can be an axial actuator. The actuator 120 can be a voice coil actuator, a piezoelectric actuator, a stepper motor, a servo motor, or a thermal expansion actuator. The actuator 120 includes a fixed portion 122 that is coupled to a frame and a moving portion 124 that is adapted to supply a force in a linear direction. In the implementation, the moving portion 124 is adapted to move in the Z-direction. In the following specification, the conceptual figures represent fixed portions (such as the frame) in the standard manner as a single line with several hatched lines connected to it.

The system 100 can include one or more flexures. In FIG. 1, the system 100 includes a flexure 142 and a flexure 144. The flexures 142 and 144 have different numbers of degrees of freedom. In a particular implementation, the flexure 142 can have one degree of freedom, and the flexure can have five degrees of freedom. In an implementation, the flexure 142 can be a guiding flexure that allows movement in a desired direction, the Z-direction in FIG. 1. In the same or different implementation, the flexure 144 can be a decoupling flexure that helps keep movement in other directions and rotations from exceeding tolerances. The other directions can include an X-direction, Y-direction, and the rotations can include rotation about axes in the X-direction, the Y-direction, and the Z-direction. Such rotations can be expressed as angles, for example, θ_{X}, θ_{Y}, and θ_{Z}.

The flexure 142 can be coupled to the actuator 120, and more particularly, the moving portion 124 of the actuator 120, and to the flexure 144. In an implementation, the flexure 142 can include a base and a moving portion. The base may be coupled to the same frame or a different frame as compared to the actuator 120. The moving portion of the flexure 142 can be connected to the flexure 144 and can also be connected to the moving portion 124 of the actuator 120. In an implementation, the flexure 142 can include a parallelogram-based structure.

The flexure 144 can be a decoupling flexure. The flexure 144 can have a proximal end coupled to the flexure 142 and a distal end coupled to a movable object 160. In an alternative embodiment, both the proximal end of the flexure 144 and the moving portion of the flexure 142 have a parallel connection to the actuator's moving portion 124. In another alternative embodiment, the proximal end of the flexure 144 is connected to the moving portion 124 of the actuator 120, and the moving portion of the flexure 142 is connected to the proximal end of the flexure 144. In an implementation, the proximal end of the flexure 144 can be connected to the flexure 142, and the distal end of the flexure 144 can be connected to the movable object 160. The movable object 160 may or may not be part of the system 100.

As used in this specification, a coupling can include a connection between two or more objects. However, not all couplings are connections. Two or more objects are coupled, and not connected, when movement of a first object does not result in the same movement at the same time in another object. The actuator 120 can be coupled to the movable object 160 via the flexures 142 and 144. The actuator 120 may not be connected to the movable object 160 but they may be coupled to each other. Thus, connections are a subset of couplings, and not all couplings are connections.

Regarding connections, two or more objects are connected if such two or more objects remain in a fixed position relative to each other and do not detectibly move with respect to each other. A connection may or may not have physical contact between two objects. For example, regarding no physical contact, the two objects may be spaced apart from and not physically contact each other because a washer or a gasket may lie between two objects. The two objects and the washer or gasket are parts of a physical connection because the two objects and the washer or the gasket remain in fixed position relative to one another. In another implementation, the washer or the gasket may not be present, and the two objects contact each other. Thus, connections between two objects may or may not have physical contact the two objects.

FIG. 2 includes a side view of a flexure 242 that is an example of the flexure 142. The flexure 242 can have a parallelogram-based structure and include a single parallelogram. A base 260 can be coupled to the frame, and a moving portion 268 can be coupled to the proximal end of the flexure 144. The moving portion 268 can be coupled to the base 260 by blade(s) 262. The blades 262 can be coupled at or near ends of the moving portion 268. In FIG. 3, when a force, F, in the Z-direction is applied to the moving portion 268, the moving portion 268 moves a distance δ_{Z} in the Z-direction and a distance δ_{X} in the X-direction and is illustrated with the dashed line features in FIG. 3.

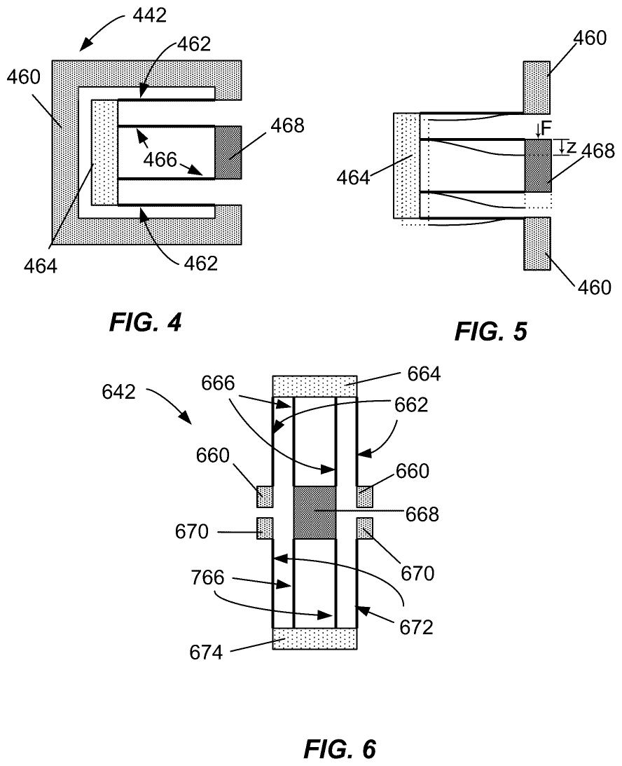

FIG. 4 includes a side view of a flexure 442 that is an example of the flexure 142. The flexure 442 can have a parallelogram-based structure and include one double parallelogram. A base 460 can be coupled to the frame, and a moving portion 468 can be coupled to the proximal end of the flexure 144. The base 460 can be coupled to an intermediate body 464 by blades 462, and the moving portion 468 can be coupled to the intermediate body 464 by blades 466. The blades 462 can be coupled at or near ends of the intermediate body 464, and the blades 466 can be coupled at or near ends of the moving portion 468.

In FIG. 5, only portions of the base 460 are illustrated. When a force, F, in the Z-direction is applied to the moving portion 468, the moving portion 468 moves δ_{Z} in the Z-direction. The blades 462 can bend in one direction, and the blades 466 can bend in a different direction. Unlike the flexure 242 in FIG. 2, the moving portion 468 in the flexure 442 may not have any measurable movement in the X-direction. The intermediate body 464 can move in the Z-direction and the X-direction. The amount of movement can depend on the design of the blades 462 and 466 and their relative positions with respect to the base 460, the intermediate body 464, and the moving portion 468.

The flexure can include a parallelogram-based structure and include more than one double parallelogram. FIG. 6 includes a flexure 642 that includes two double parallelograms. A base 660, blades 662 and 666, and a intermediate body 664 are similar to the base 460, the blades 462 and 466, and the intermediate body 464, respectively, in FIG. 4. A base 670, blades 672 and blades 676, and an intermediate body 674 are similar to the base 460, the blades 462 and 466, and the intermediate body 464, respectively, in FIG. 4. The moving portion 668 is coupled to the blades 666 and 676. The flexure 642 can provide more stiffness than the flexure 442 when the blades 462, 466, 662, 666, 672, and 676 are made from the same material, have the same thickness, and the same geometry. The flexure 642 occupies more volume than the flexure 442. After reading this specification, skilled artisans will be able to determine the particular design for the guiding flexure that meets the needs and desires for a particular application.

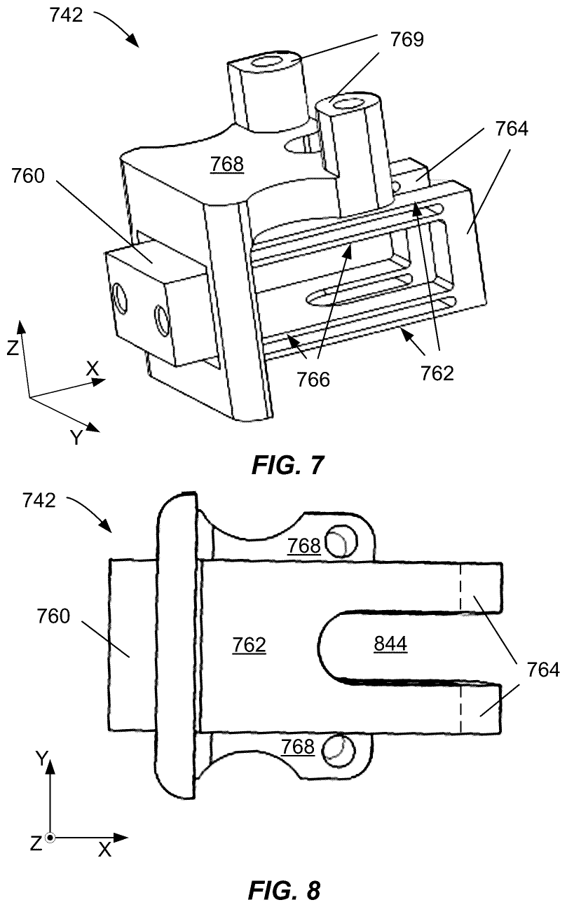

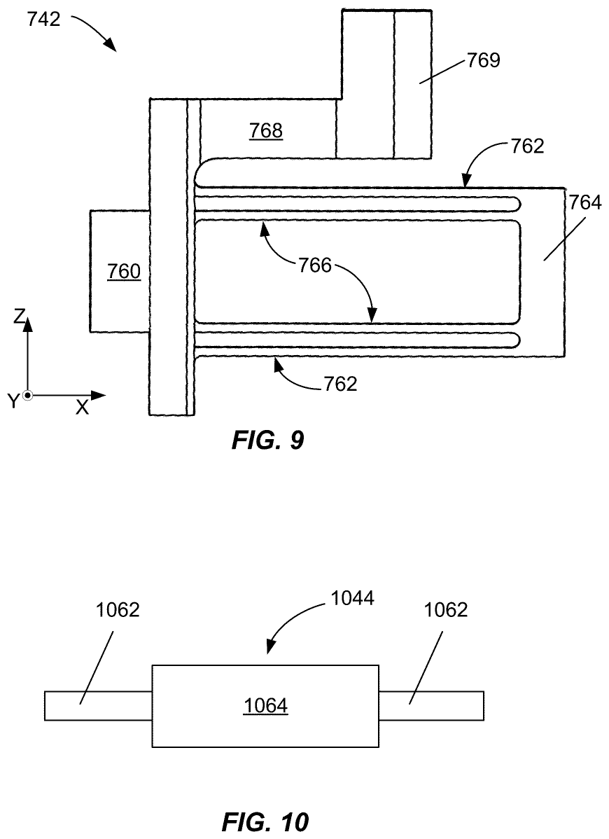

In FIGS. 7 to 13, particular flexures are described that can be used for a particular application with an axial actuator. The concepts for flexures as described herein are not limited to the designs and features illustrated and described in FIGS. 7 to 13.

FIGS. 7, 8, and 9 include a perspective view, a bottom view, and a side view of a flexure 742. The flexure 742 can have a one double parallelogram structure. In the implementation illustrated, the base 760 extends through an opening in the moving portion 768. The base 760 can include openings that allow the base 760 to be secured to a frame (not illustrated). The base 760 can be coupled to blades 762 that can be coupled to intermediate bodies 764. The intermediate bodies 764 can be coupled to blades 766 that can be coupled to the moving portion 768. Posts 769 can allow the flexure 742 to be coupled to an actuator, another flexure, or another object.

The flexure 742 can have an opening 844 through which a portion of the other flexure can be positioned. The opening 844 can be in the form of a slot as illustrated in FIGS. 7 and 8. The slot can extend from near the center of the blades 762 and 766 to the right-hand side of the flexure 742. The intermediate bodies 764 are spaced apart from each other by the opening 844. The opening 844 allows for the flexure 742 and the other flexure to occupy less area than if the opening 844 was not present. In another implementation (not illustrated), the opening 844 does not need to extend to the right-hand end of the flexure 742. From a top view or a bottom view, the opening 844 can have a closed shape, such as a circle, a rectangle (that may or may not be a square), a hexagon, an octagon, or an irregular polygon.

FIG. 10 includes a conceptual view of a flexure 1044 that can be used for the flexure 144 in FIG. 1. The flexure 1044 can be a wire flexure and include a midsection 1064 and end sections 1062 that are located at opposite ends of the midsection 1064. Each of the midsection 1064 and the end sections 1062 can have a cylindrical shape. The midsection 1064 can have a diameter that is greater than diameters of the end sections 1062. The larger diameter can help to reinforce the middle of the flexure 1044. The buckling capacity of the flexure 1044 can increase by approximately the square of a quotient that is the diameter of the midsection 1064 divided by the diameter of the end sections 1062. When the diameter of the midsection 1064 is two times the diameter of the end sections 1062, the buckling load capacity of the flexure 1044 can increase by four times, and when the diameter of the midsection 1064 is three times the diameter of the end sections 1062, the buckling load capacity of the flexure 1044 can increase by nine times.

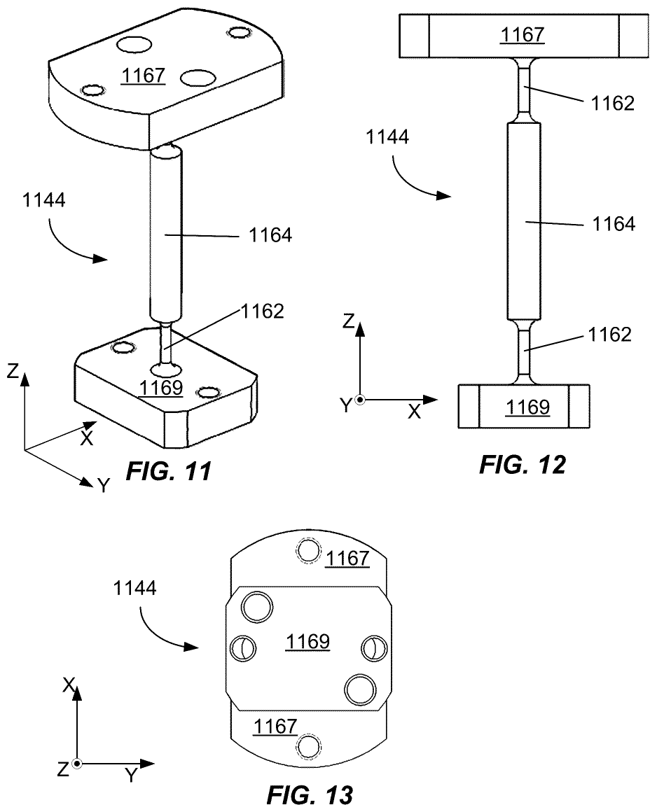

FIGS. 11, 12, and 13 include a perspective view, a side view, and a bottom view of a flexure 1144, that includes the flexure design illustrated in FIG. 10. The flexure 1144 can be a decoupling flexure, and in particular, can be a wire flexure. The flexure 1144 can include a midsection 1164 and end sections 1162. The construction of the midsection 1164 and the end sections 1162 can have any of the constructions as described with respect to the flexure 1044 in FIG. 10. The flexure 1144 can include mounting plates 1167 and 1169 that are spaced apart from the midsection 1164 by the end sections 1162. The mounting plate 1167 can be at a proximal end of the flexure 1144 that will be coupled to the moving portion 768 of the flexure 742 in FIGS. 7 to 9. The mounting plate 1169 can be at a distal end of the flexure 1144 that can be coupled to a movable object.

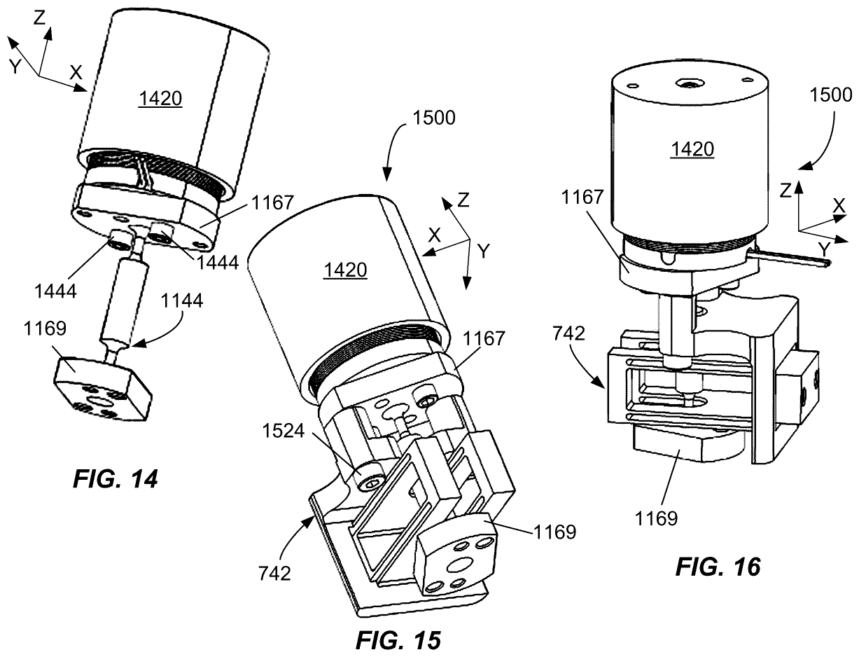

FIG. 14 includes a perspective view of an actuator 1420 coupled to the proximal plate 1167 of the flexure 1144. In FIGS. 14 to 25, except possibly for wires, electrical connections and other electrical couplings are present but not illustrated to improve understanding of positional relationships between components within a module that can be used in a die bonding head.

The actuator 1420 can be any of the actuators previously described with respect to the actuator 120 in FIG. 1. In an implementation, the actuator 1420 and the flexure 1144 can be connected to each other. In a more particular implementation, the mounting plate 1167 at the proximal end of the flexure 1144 can physically contact a moving portion of the actuator 1420. In the same or different implementation, fasteners 1444 can be used to connect the actuator 1420 to the flexure 1144. The fasteners 1444 can be bolts, screws, or another suitable fastener to connect the actuator 1420 to the flexure 1144. In a different implementation, the actuator 1420 and the flexure 1144 can be connected using an adhesive or welded together.

FIGS. 15 and 16 include perspective views of an actuator system 1500 that includes the actuator 1420 and the flexure 1144 in FIG. 14, and further includes the flexure 742. The coupling between the actuator 1420 and the flexure 1144 is addressed with respect to FIG. 14. The flexure 742 is coupled to the flexure 1144 and the actuator 1420. In an implementation, the flexure 742, the flexure 1144, and the actuator 1420 are connected together. In an implementation, the flexure 742 and the actuator 1420 are spaced apart from each other and do not contact each other. In the same or different implementation, the mounting plate 1167 of the flexure 1144 is located between the flexure 742 and the actuator 1420.

The combination of the actuator 1420 and the flexure 1144 in FIG. 14 can be inserted into the opening 844 of the flexure 742. Referring to FIGS. 7 and 8, the opening 844 is open-ended and extends in the X-direction between the intermediate bodies 764 and into the blades 762 and 766. The open-ended opening 844 allows the flexure 1144 to be inserted more easily into the opening 844 during assembly. In a different implementation, a close-ended opening may be used that does not extend to the right-hand side of the flexure 742 (compare to the opening 844 in FIG. 8). A single intermediate body may replace the intermediate bodies 764. Such an implementation may be used; however, at least a portion of the flexure 1144 may need to be assembled or disconnected and reassembled after the midsection 1164 and at least one of the end sections 1162 of the flexure 1144 would pass through the close-ended opening of the other flexure. The flexure 1144 passes through the blades 762 and 766 without touching the blades. This is accomplished by providing an opening 844 in those blades 762 and 764 and arranging the flexure within that opening. The shapes of the blades 762 and 764 define the opening 844 to be large enough that the flexure 1162 can move within the opening 844 without touching the blades 762 and 764.

Fasteners 1524, one of which is illustrated in FIG. 15, can be used to connect the flexure 742 to the flexure 1144. The fasteners 1524 can be bolts, screws, or another suitable fastener to connect the flexure 742 to the flexure 1144. In a different implementation, the flexure 742 and the flexure 1144 can be connected using an adhesive or welded together.

In FIGS. 14 to 16, the flexure 1144 is coupled to the actuator 1420 before the flexure 742 is coupled to the combination of the flexure 1144 and the actuator 1420. In another implementation, the order may be reversed, where the flexures 742 and 1144 are coupled together before the actuator 1420 is coupled to the combination of the flexures 742 and 1144.

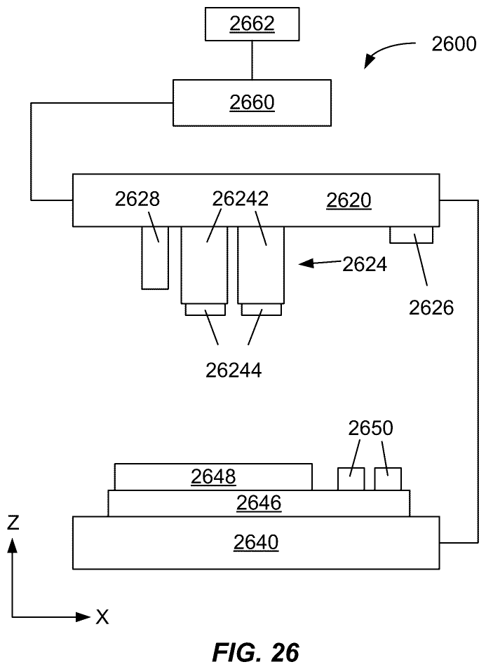

The actuator system 1500 can be used as a sub-assembly within a larger system, such as module within a die bonding head within a die bonding system. In the description below, parts of the die bonding head are described with respect to the actuator system 1500, and the die bonding system will be illustrated and described with respect to bonding a set of dies to die bonding sites of a bonding substrate. FIG. 26 includes a conceptual view of a non-limiting die bonding system 2600.

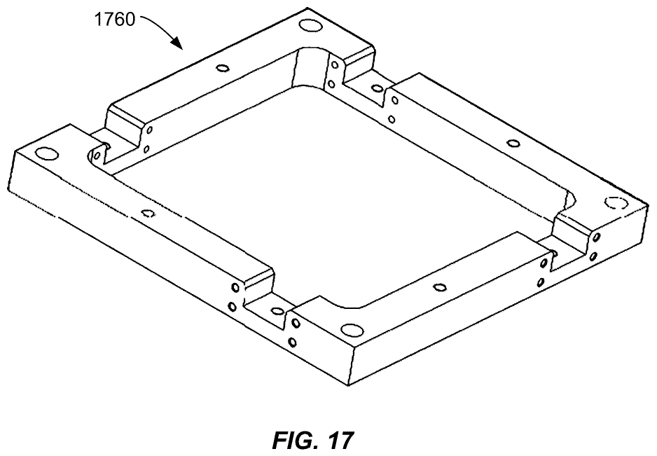

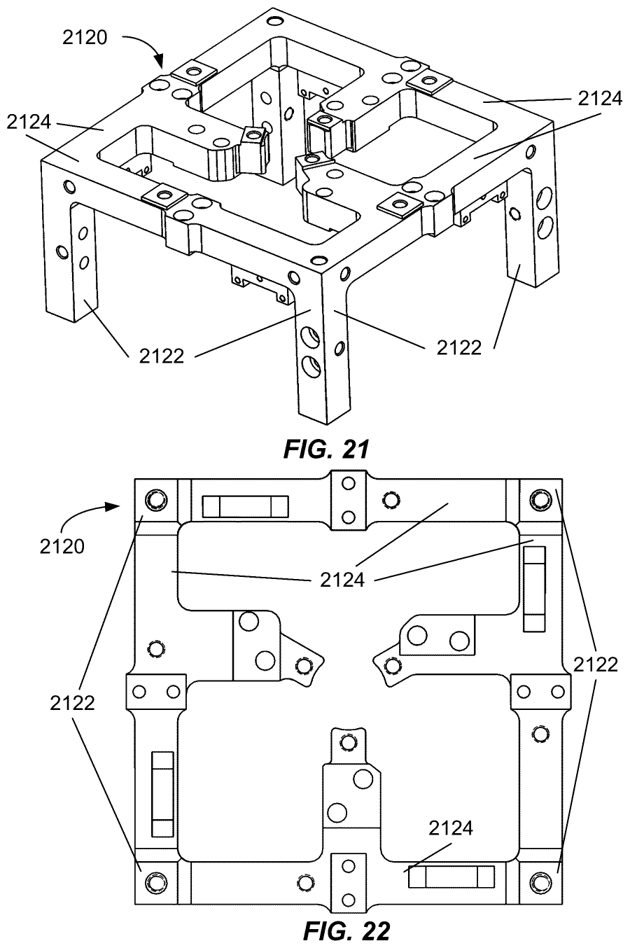

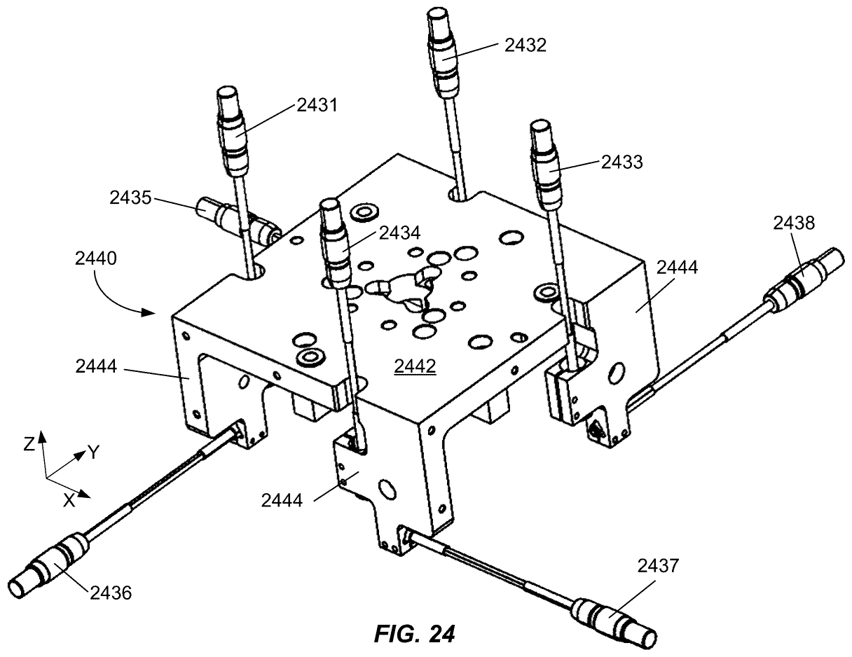

A plurality of the actuator systems 1500 can be coupled to a frame that can include any one or a combination of a lower frame member (FIG. 17), an internal frame member (FIGS. 21 and 22), and an upper frame member (FIG. 24). FIG. 17 includes a lower frame member 1760.

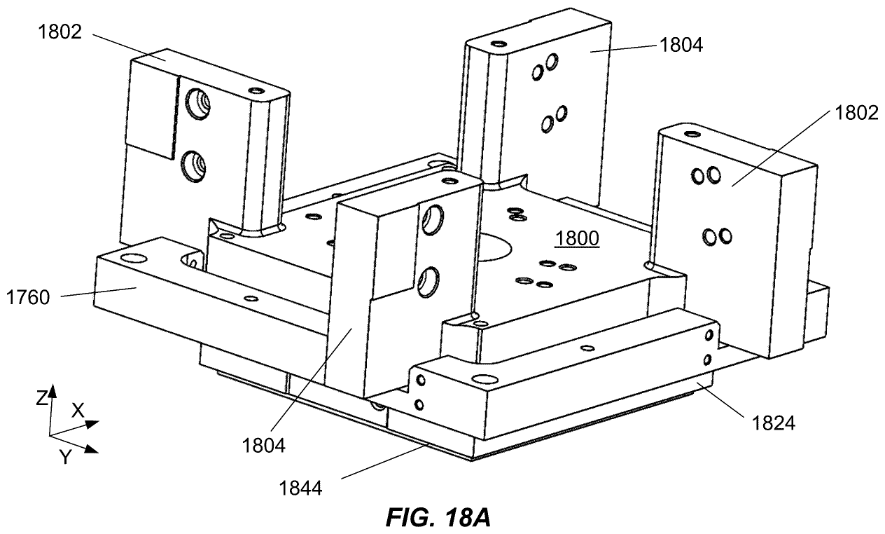

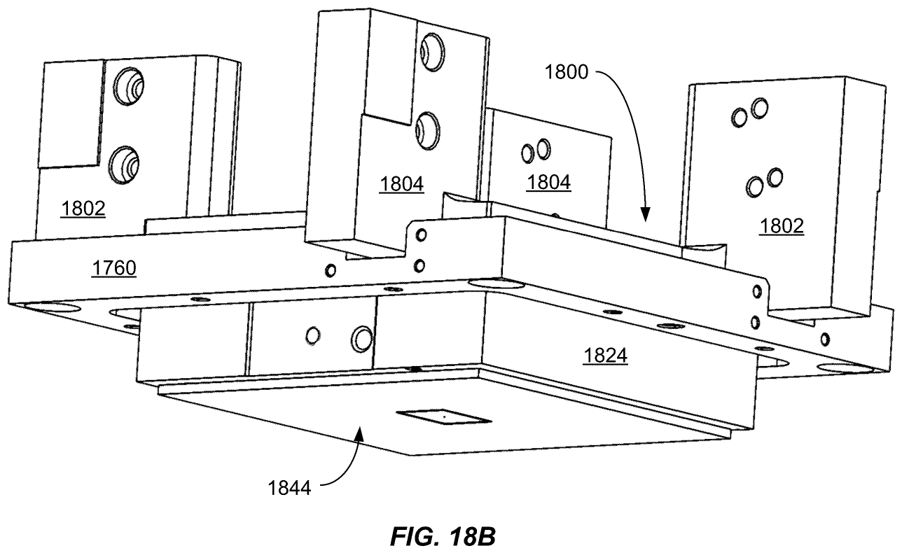

FIGS. 18A and 18B include illustrations of the lower frame member 1760, a movable platform 1800, a die chuck holder 1824, and a die chuck 1844. FIGS. 18A and 18B are perspective views from different view angles to provide a better understanding of the positional relationships between the components in the figures. The movable platform 1800 includes an upper surface as illustrated in FIG. 18A. FIG. 18B illustrates the die chuck holder 1824 that is coupled to a lower surface, opposite the upper surface, to which the die chuck holder 1824 is coupled. The die chuck 1844 can be coupled to the bottom surface of the movable platform 1800. In an implementation, the die chuck holder 1824 is connected to the movable platform 1800 and may or may not contact the movable platform 1800. The die chuck holder 1824 is located between the movable platform 1800 and the die chuck 1844. The die chuck 1844 can be releasably coupled to a die chuck retention zone of the die chuck holder 1824, where the die chuck retention zone is along a bottom surface of the die chuck holder 1824. The movable platform 1800 can allow a die coupled to the die chuck 1844 that can be coupled to the movable platform 1800 to be precisely positioned with respect to its corresponding die bonding site of the bonding substrate. Different dies may use the same die chuck, such as die chuck 1844, or different die chucks. Thus, the die chuck 1844 may be held by the die chuck holder 1824 when bonding first dies and released after the first dies are bonded. A different die chuck (not illustrated) can then be held by the die chuck holder 1824 when second dies that are different from the first dies are to be bonded to the same or a different bonding substrate.

The movable platform 1800 further includes tabs 1802 and 1804. The tabs 1802 and 1804 are adapted to be coupled to actuator systems that will be oriented for motion in the X-Y plane. In FIG. 18, the movable platform 1800 is not connected to any or all of the lower frame member 1760 and the jig 1840.

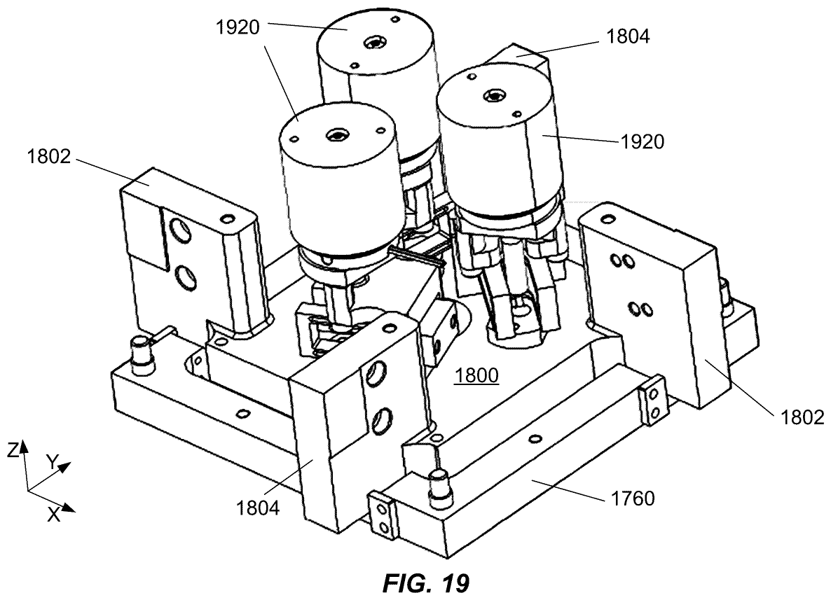

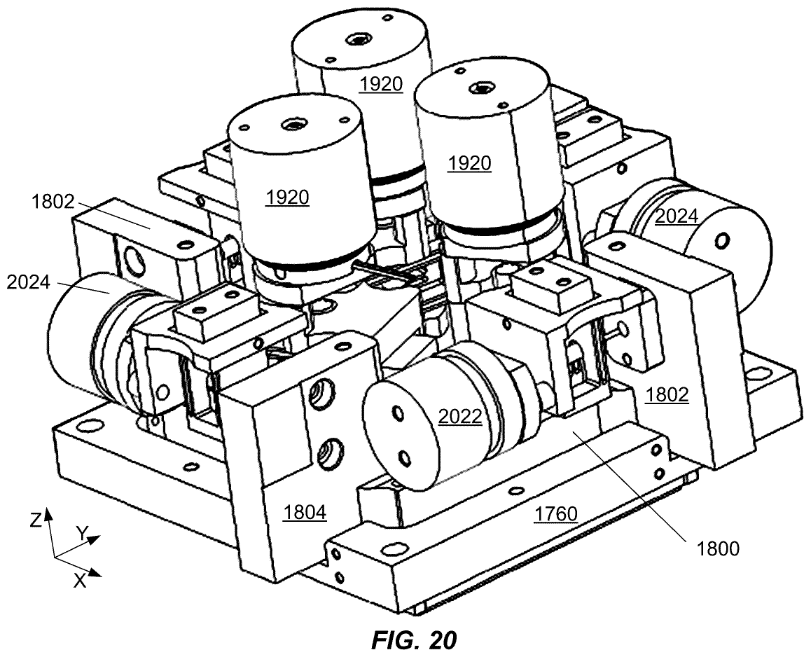

FIG. 19 includes a perspective view of the portion of the module and further includes actuator systems 1920. Any one or more of the actuator systems 1920 can have a construction that is the same as the actuator system 1500. For example, any or all of the actuator systems 1920 can include the actuator 1420 and the flexures 742 and 1144. The actuator systems 1920 can be coupled to the upper surface of the movable platform 1800. In an implementation, the distal plates of the actuator systems 1920 are connected to the upper surface of the movable platform 1800. The combination of the actuator systems 1920 can control motion of the movable platform 1800 in the Z-direction, rotation about an X-direction axis passing through the center of compliance of the movable platform θ_{X} (also referred to as tip), and rotation about a Y-direction axis passing through the center of compliance of the movable platform, θ_{Y} (also referred to as tilt).

FIG. 20 includes a perspective view of the portion of the module and further includes actuator systems 2022 and 2024. Any one or more of the actuator systems 2022 and 2024 can have a construction that is the same as the actuator system 1500. For example, any or all of the actuator systems 2022 and 2024 can include the actuator 1420 and the flexures 742 and 1144. The actuator systems 2022 can be coupled to the tabs 1802, and the actuator systems 2024 can be coupled to the tabs 1804. In an implementation, the distal plates of the actuator systems 2022 can be connected to the tabs 1802, and the distal plates of the actuator systems 2024 can be connected to the tabs 1804. The actuator systems 2022 can be oriented to drive the movable platform 1800 principally in the X-direction, and the actuator systems 2024 can be oriented to drive the movable platform 1800 principally in the Y-direction. The combination of actuator systems 2022 and 2024 can control motion of the movable platform 1800 in the X-direction, Y-direction, and rotation about a Z-direction axis passing through the center of compliance of the movable platform, θ_{Z}.

FIGS. 21 and 22 include a perspective view and a bottom view, respectively, of an internal frame member 2120. The internal frame member 2120 can include cross members 2124 and legs 2122 extending from the cross members 2124.

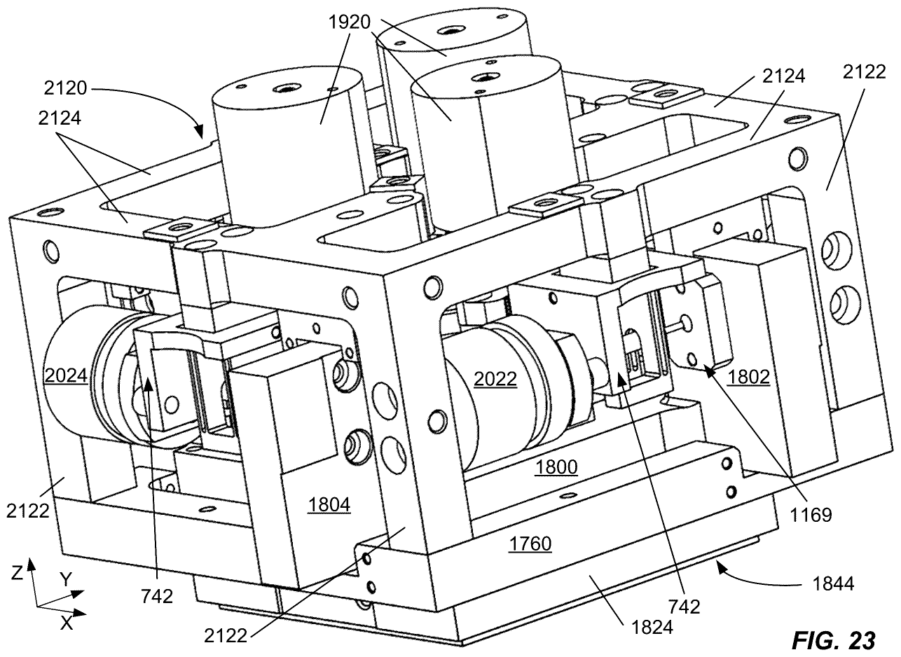

FIG. 23 includes a perspective view of the portion of the module and further includes the internal frame member 2120. The internal frame member 2120 can be coupled to the lower frame member 1760. In an implementation, the internal frame member 2120 can be connected to the lower frame member 1760. In the same or different implementation, fasteners (not illustrated) can be used to connect together the internal frame member 2120 and the lower frame member 1760. The fasteners can be bolts, screws, or another suitable fastener to connect the internal frame member 2120 to the lower frame member 1760. In a different implementation, the internal frame member 2120 and the lower frame member 1760 can be connected using an adhesive or welded together.

The actuator systems 2022 and 2024 can be coupled to the internal frame member 2120. In an implementation, the actuator systems 2022 and 2024 can be connected to the internal frame member 2120. In a particular implementation, the fixed portions of the actuators 1420 can be connected to legs 2122 of the internal frame member 2120, and bases of the flexures 742 can be connected to the cross members 2124 of the internal frame member 2120.

The actuator systems 2022 and 2024 can be coupled to the movable platform 1800. In an implementation, the actuator systems 2022 and 2024 can be connected to the movable platform 1800. In a particular implementation, mounting plates 1169, one of which is illustrated in FIG. 23, near the distal ends of the flexures 1144 can be connected to the tabs 1802 and 1804, respectively, of the movable platform 1800.

In the same or different implementation, fasteners can be used to connect the actuator systems 2022 and 2024 to the internal frame member 2120 and the tabs 1802 and 1804. The fasteners can be bolts, screws, or another suitable fastener to connect the actuator systems 2022 and 2024 to the internal frame member 2120 and the tabs 1802 and 1804. In a different implementation, any one or more of the actuator systems 2022 and 2024, the internal frame member 2120 and the movable platform 1800 can be connected using an adhesive or welded together.

FIG. 24 includes a perspective view of an upper frame member 2440 that includes a top portion 2442 and leg portions 2444 extending from corners of the top portion 2442. FIG. 24 further includes position sensors 2431, 2432, 2433, 2434, 2435, 2436, 2437, and 2438 that can be used to determine the position of the movable platform 1800 (illustrated in FIGS. 18 to 20). The position sensors 2431, 2432, 2433, 2434, 2435, 2436, 2437, and 2438 can be based on capacitance, light received by the sensors, or proximity between any of the sensors and an object sensed by the sensors. The positions sensors 2431, 2432, 2432, 2434, 2435, 2436, 2437, and 2438 can be of one or more types of position sensors including: capacitive sensors; inductive proximity sensors; hall effect sensor; magnetostrictive sensors; optical micrometer; spectral interference displacement sensors; and confocal displacement sensors. Each of the position sensors is a noncontact sensor that supplies a signal regarding a position of the movable platform 1800 along one or more axes to the controller 2660. In an implementation, the position sensors 2431, 2432, 2433, 2434, 2435, 2436, 2437, and 2438 may be connected to other portions of a bonding head body (not illustrated in FIG. 24) and pass through any one or more of the frame members 2120, 2440, and 1760. In another implementation, the position sensors 2431, 2432, 2433, 2434, 2435, 2436, 2437, and 2438 may be connected to any one of the frame members 2120, 2440, and 1760. In a further implementation, more or fewer position sensors may be present.

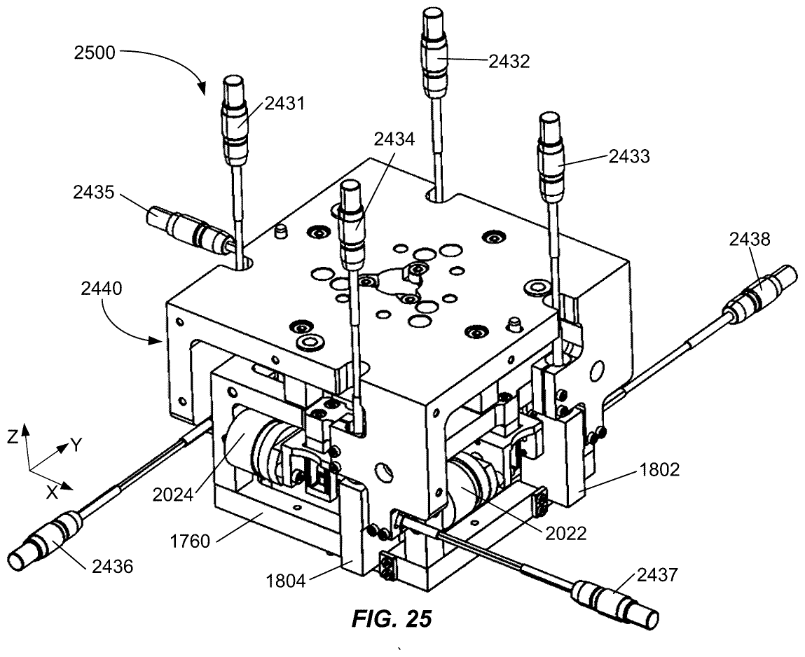

FIG. 25 includes a perspective view of a die chuck retention and positioning module 2500. The module 2500 includes the portion of the module in FIG. 23 and can further include the upper frame member 2440 that can be coupled to other components within the module 2500. The die chuck holder 1824 and the die chuck 1844 are not illustrated in FIG. 25 to simplify understanding of the module 2500.

The upper frame member 2440 can be coupled to the internal frame member 2120 and the lower frame member 1760. In an implementation, the upper frame member 2440 can be connected to the internal frame member 2120, which can be connected to the lower frame member 1760. In the implementation illustrated, the upper frame member 2440 is spaced apart from and does not contact the lower frame member 1760. Fixed portions of the actuators 1420 within the actuator systems 1920 (FIG. 23) can be coupled to a bottom surface of the top portion 2442 of the upper frame member 2440. In an implementation, fixed portions of the actuators 1420 can be connected to the bottom surface of the top portion 2442. In the same or different implementation, fasteners can be used to connect the fixed portions of the actuators 1420 to the top portion 2442. The fasteners can be bolts, screws, or another suitable fastener to connect the fixed portions of the actuators 1420 to the top portion 2442. In a different implementation, fixed portions of the actuators 1420 and the top portion 2442 can be connected using an adhesive or welded together.

The module 2500 can be used with a die bonding system 2600 in FIG. 26. The die bonding system 2600 can be a single apparatus or more than one apparatus. In an implementation, the die bonding system 2600 may include another apparatus or equipment not illustrated in FIG. 26.

The die bonding system 2600 includes a bridge 2620, a base 2640, and a controller 2660 that is coupled to the bridge 2620, the base 2640, or one or more components coupled to the bridge 2620 or the base 2640. The bridge 2620 can be coupled to an array of bonding heads 2624, a reference 2626 having one or more alignment marks, and registration hardware 2628. The base 2640 can be coupled to a bonding carriage 2646. Although not illustrated, the die bonding system 2600 may include die transfer seats (for example, pick-up heads, part of a pick-and-place tool, etc.) that can be used to transfer dies to the array of bonding heads 2624. The die bonding system 2600 and may optionally further include a source chuck (not illustrated) coupled to the bridge 2620, where the source chuck can be used to hold a source substrate that includes dies to be bonded to a bonding substrate.

In FIG. 26 and other figures, the bridge 2620, the base 2640, and components physically between the bridge 2620 or the base 2640 can be organized along an X-direction, a Y-direction, a Z-direction, or a combination thereof. With respect to cross-sectional or side views, the X-direction is between the left-hand and right-hand sides of the drawings, the Z-direction is between the top and bottom of the drawings, and the Y-direction is into and out of the drawing sheet.

The array of bonding heads 2624 can be arranged as a vector (a row or a column of bonding heads) or as a matrix (at least two rows and at least two columns of bonding heads). Regarding the matrix, the number of bonding heads within the array of bonding heads 2624 may be different between rows, between columns, or between rows and columns. Some array configurations can include 3×1, 6×1, 2×2, 2×3, 2×4, 4×2 10×10, or another rectangular shape, where the first number corresponds to the number of bonding heads along a row or column, and the second number corresponds to the number of bonding heads along the other of the row or column. In theory, dies from an entire wafer may be transferred all at once. For such a configuration, from a bottom view, the array of bonding heads 2624 may have fewer bonding heads along rows closer to the top and bottom of the array as compared to the row or the pair of rows closest to the center of the array, and the array of bonding heads 2624 may have fewer bonding heads along columns closer to the left-hand side and right-hand side of the array as compared to the column or the pair of columns closest to the center of the array. After reading this specification, skilled artisans will be able to determine an arrangement for the array of bonding heads 2624 that meets the needs or desires for a particular application.

Any or all of the bonding heads within the plurality of bonding heads 2624 can include a bonding head body 26242 and a die chuck 26244. The bonding head body 26242 can include the die chuck retention and positioning module 2500 and the die chuck holder 1824. The bonding head body 26242 can be coupled to a die chuck 26244 within a die chuck retention zone along a bottom surface of the movable platform 1800 (illustrated in FIG. 18). The die chuck 26244 can be the same as or different from the die chuck 1844 in the previous figures. The die chuck 26244 can be a vacuum chuck, a pin-type chuck, a groove-type chuck, an electrostatic chuck, an electromagnetic chuck, an edge gripping chuck, or a Bernoulli chuck. The die chuck 26244 can be adapted to modulate the shape of a die during a die bonding sequence.

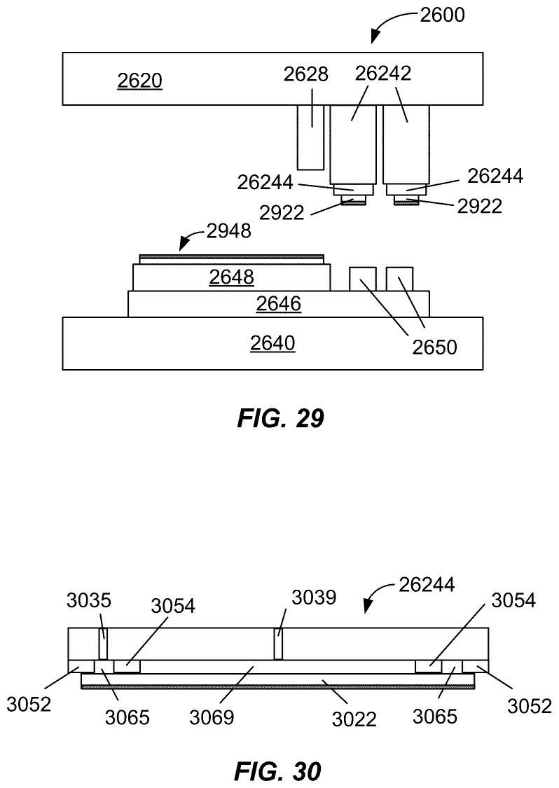

Registration hardware 2628 is coupled to the bridge 2620. The registration hardware 2628 can include an optical component and provide information to the controller 2660 or a local controller located within the registration hardware 2628, the bridge 2620 or another component coupled to the bridge 2620, the base 2640 or a component coupled to the base 2640, or a combination thereof. The information from the registration hardware 2628 can be used to determine a bonding pitch for the die bonding sites of a bonding substrate 2948 (illustrated in FIG. 29). Further, the information may be used to identify or confirm the bonding substrate 2948 is the correct substrate to which dies will be transferred and the position of bonding sites on the bonding substrate 2948.

Registration hardware 2650 can be coupled to the bonding carriage 2646. The registration hardware 2650 can include an optical component and provide information to the controller 2660 or a local controller located within the registration hardware 2650, the bonding carriage 2646, the bridge 2620 or a component coupled to the bridge 2620, the base 2640 or another component coupled to the base 2640, or a combination thereof. The registration hardware 2650 can be used to align the bonding carriage 2646 to the one or more alignment marks of the reference 2626, align the bonding carriage 2646 to the array of bonding heads 2624, or both. The registration hardware 2650 can be to provide information used in adjusting positions of the die chucks 26244 within the array of bonding heads 2624.

The die bonding system 2600 can be controlled by the controller 2660 in communication with the bridge 2620, any component coupled to the bridge 2620, the base 2640, any component coupled to the base 2640, or a combination thereof. The controller 2660 can operate using a computer readable program, optionally stored in memory 2662. The controller 2660 can include a processor (for example, a central processing unit of a microprocessor or microcontroller), a field-programmable gate array (FPGA), an application specific integrated circuit (ASIC), or another electrical component adapted to carry out instructions in hardware, software, or firmware. The controller 2660 can further include internal memory, such as a set of registers, a cache memory, a flash memory, or another suitable memory. The controller 2660 can be within the die bonding system 2600. In another implementation (not illustrated) of the die bonding system, the controller 2660 can be at least part of a computer external to the die bonding system 2600, where such computer is bidirectionally coupled to the die bonding system 2600. The controller 2660 can include one processor or a plurality of processors that communicate over a bus, a local area intranet, or a wide area internet. In another implementation, the bridge 2620, a component coupled to the bridge 2620, the base 2640, or a component coupled to the base 2640 can include a local controller that provides some of the functionality that would otherwise be provided by the controller 2660.

The memory 2662 can include a non-transitory computer readable medium that includes instructions to carry out the actions associated with a hybrid bonding operation. The memory 2662 can include a non-transitory computer readable medium that includes instructions to carry out the actions associated with a die bonding operation. The memory 2662 can include a set of registers, a cache memory, a flash memory, a hard drive, or another memory. The memory 2662 can further include data tables that can be accessed by the controller 2660 to assist in determining an operating parameter, for example, positioning a movable platform in an X-Y plane, bonding a die to a bonding substrate within the die bonding system 2600, or both as described below.

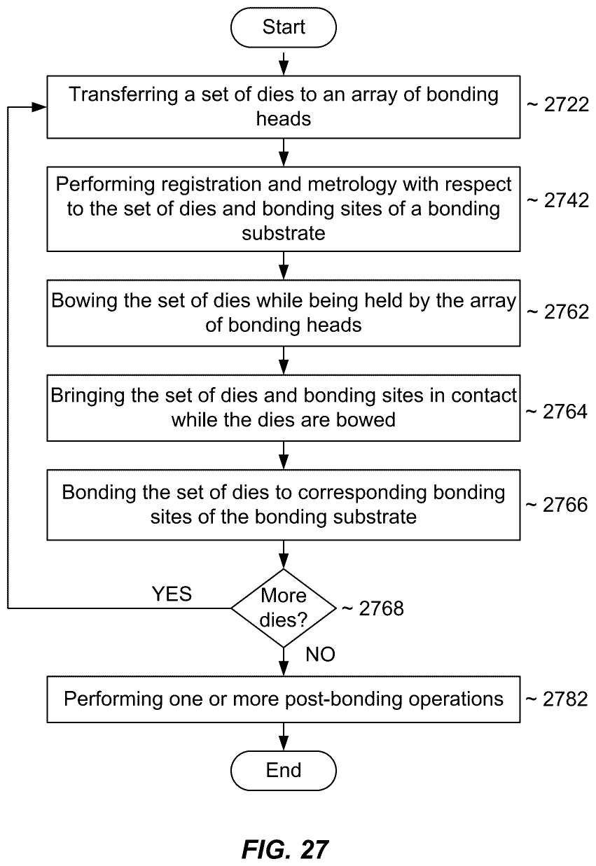

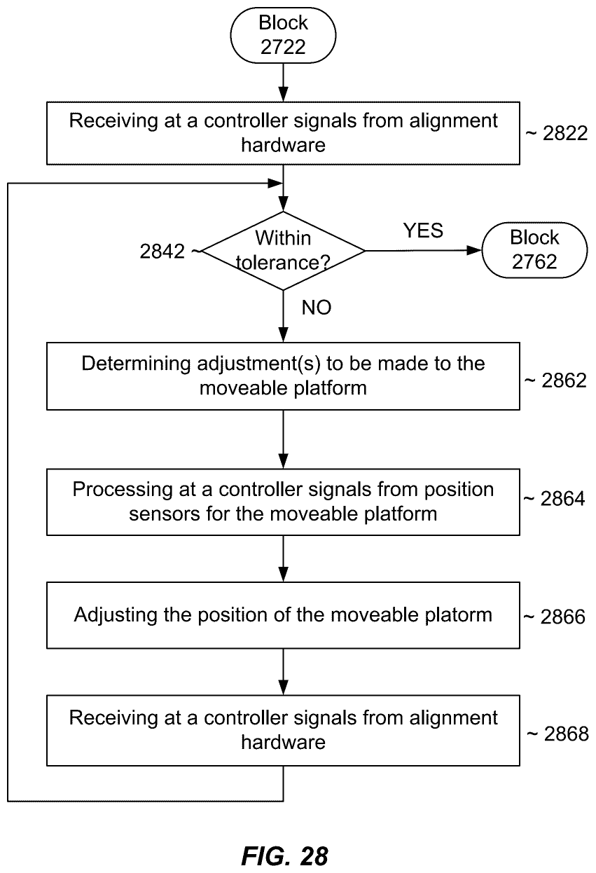

Attention is directed to methods of bonding dies to die bonding sites of a bonding substrate using the die bonding system 2600 when transferring a set of dies to die bonding sites of a bonding substrate. The process flow for the method is illustrated in FIG. 27. FIG. 28 includes details for at least some of the actions that can occur when performing the operation in block 2742 in FIG. 27.

The method can include transferring a set of dies to an array of bonding heads at block 2722 in FIG. 27. In FIG. 29, a die transfer carriage (not illustrated) and the bonding carriage 2646 are moved to the right. The die transfer carriage is moved so that the array of bonding heads 2624 is over the array of die transfer seats. If needed or desired, the registration hardware 2628, 2650, or both can be used to confirm the array of die transfer seats (not illustrated) is properly positioned with respect to the array of bonding heads 2624. The controller 2660 or a local controller can transmit a signal for the die transfer seats within the array of die transfer seats to be extended toward the bonding heads within the array of bonding heads 2624, for the bonding heads within the array of bonding heads 2624 to be extended toward the die transfer seats within the array of die transfer seats, or both. A set of dies 2922 is retained by die chucks 26244. A bonding substrate 2948 can be coupled to the substrate chuck 2648. The dark bands along the set of dies 2922 and the bonding substrate 2948 represent activated surfaces to assist in bonding the set of dies 2922 to the bonding substrate 2948. In a non-limiting implementation, the activated surfaces can be hydrolyzed surfaces of a silicon oxide material.

FIG. 29 includes the set of dies 2922 after being transferred from the array of die transfer seats to the array of bonding heads 2624. FIG. 30 includes a particular die 3022 within the set of dies 2922 that is held by the die chuck 26244. The actions described with respect to the particular die 3022 are also performed with respect to the other dies within the set of dies 2922. Referring to FIGS. 26, 29 and 30, the controller 2660 or a local controller can transmit a signal for a pressure actuator for a bonding head within the array of bonding head 2624 to activate the pressure actuator to evacuate a flow channel 3035 and a zone 3065 between lands 3052 and 3054. The vacuum within the zone 3065 can be sufficient to hold the particular die 3022. A flow channel 3039 can be at or near ambient pressure or be evacuated similar to the flow channel 3035. The controller 2660 or local controller may or may not transmit a signal to activate a pressure actuator for the flow channel 3039 to achieve the desired pressure (vacuum or at or near ambient pressure) in the flow channel 3039 and a zone 3069.

The method can further include performing registration and metrology with respect to the set of dies and bonding sites of a bonding substrate at block 2742 in FIG. 27. FIG. 28 includes at least a portion of actions performed in block 2742. A further action may or may not be performed in addition to the actions listed in FIG. 28. Thus, (1) one or more actions may occur after block 2722 in FIG. 27 and before block 2822, (2) one or more actions may occur along the YES branch of the diamond 2842 and before block 2762 in FIG. 27, or both (1) and (2).

Referring to FIG. 28, the method can include receiving at a controller 2660 signals from registration hardware at block 2822. The registration hardware 2628 can obtain information regarding the bonding substrate 2948, and the registration hardware 2650 can obtain information regarding the set of dies 2922.

The controller 2660 or a local controller can receive signals from the registration hardware 2628 regarding information for the bonding substrate 2948. The signals can include information that may or may not correspond to part number(s) for the bonding substrate 2948. Such information can be used to confirm that the correct bonding substrate 2948 is coupled to the substrate chuck 2648. If the information includes the part number, the controller 2660 or local controller can obtain from the memory 2662 or another memory further information regarding the bonding substrate 2948, such as locations of die bonding sites for the bonding substrate 2948, sizes of bonding pads for the bonding substrate 2948, topography of the bonding substrate 2948 where the set of dies 2922 will be bonded to the substrate 2948, or other information related to the surface of the bonding substrate 2948. Such information can be based on the design of the bonding substrate 2948. Thus, the information related to the bonding substrate 2948 can represent design values, and not actual values, for the parameters. The design information is not required for all implementations, and thus, obtaining the design information may or may not be performed.

Alternatively, or in addition to the design values, the information for actual values for locations of die bonding sites for the bonding substrate 2948, sizes of bonding pads for the bonding substrate 2948, topography of the bonding substrate 2948 where the set of dies 2922 will be bonded to the substrate 2948, or other information related to the surface of the bonding substrate 2948 can be determined by the controller 2660 or a local controller based at least in part on signals transmitted by the registration hardware 2628 and received by the controller 2660 or a local controller.

The controller 2660 or a local controller can receive signals from the registration hardware 2650 regarding information the set of dies 2922. The signals can include information that may or may not correspond to part number(s) for the set of dies 2922. Such information can be used to confirm that the correct dies will be bonded to the bonding substrate 2948. If the information includes part number(s), the controller 2660 or local controller can obtain from the memory 2662 or another memory further information regarding the set of dies 2922, such as areal dimensions of dies within the set of dies 2922, locations of bonding pads within the dies of the set of dies 2922, sizes of bonding pads for the set of dies 2922, or other information related to the surfaces of the set of dies 2922. Such information may be based on the designs of the set of dies 2922. Thus, information related to the set of dies 2922 can represent design values, and not actual values, for the parameters. The design information may or may not assist in performing more quickly the registration or metrology. The design information is not required for all implementations, and thus, obtaining the design information may or may not be performed.

Alternatively, or in addition to the design values, the information for actual values for areal dimensions of the dies 2922, locations of bonding pads within the dies for the set of dies 2922, sizes of bonding pads for the set of dies 2922, or other information related to the surfaces of the set of dies 2922 can be determined by the controller 2660 or a local controller based at least in part on signals transmitted by the registration hardware 2628 and received by the controller 2660 or a local controller.

The controller 2660 or a local controller can use the information generated from the signals from the registration hardware 2628 and 2650 to determine whether the relative positions of the die bonding sites within the bonding substrate 2948 and the set of dies 2922 are within tolerance at decision diamond 2842 in FIG. 28. The positions can include any one or more of an X-direction difference, a Y-direction difference, a Z-direction difference, a θ_{X} difference, a θ_{Y} difference, and θ_{Z} difference. The differences can be compared to their corresponding tolerances to determine if the differences are within tolerances.

The Z-direction tolerance may be at most +/−2.5% of the length of the movable platform 1800 or at most +/−2.5% of the width of the movable platform 1800. In the same or different implementation, each of the X-direction and Y-direction tolerances may be at most +/−0.90%, at most +/−0.50%, or at most +/−0.25% of the length of the movable platform 1800 or at most +/−0.90%, at most +/−0.50%, or at most +/−0.25% of the width of the movable platform 1800. Tolerances can be expressed in terms of actual distances as compared to relative values. In an implementation, the tolerance in the X-direction, the Y-direction, or the Z-direction can be at most +/−100 nm, at most +/−50 nm, at most +/−20 nm, at most +/−10 nm, at most +/−5 nm, at most _/−2 nm, or at most +/−1 nm depending on the die being bonded.

The X-direction, the Y-direction, and the Z-direction described above can have corresponding angular tolerances. Rotations about such directions can include θ_{X}, θ_{Y}, or θ_{Z}. In an implementation, an angular tolerance for any of θ_{X}, θ_{Y}, and θ_{Z} may be at most at most +/ 50 milliradians (mrad), at most +/−20 mrad, at most +/−10 mrad, at most +/−6 mrad, or at mot +/−3 mrad.

If all of the differences are equal to or less than the tolerances, the process can proceed along the YES branch from the decision diamond 2842.

If any one or more of the differences are greater than its/their corresponding tolerance(s), the process proceeds along the NO branch from the decision diamond 2842. The method can include determining adjustment(s) to be made to the movable platform at block 2862. The position sensors 2431, 2432, 2433, 2434, 2435, 2436, 2437, and 2438 can provide information regarding the position of the movable platform 1800 before the adjustment is made. Thus, the method can include processing at a controller signals from the position sensors of the movable platform at block 2864. The controller 2660 or a local controller can receive signals from the position sensors 2431, 2432, 2433, 2434, 2435, 2436, 2437, and 2438. If information regarding the position was previously received from the position sensors 2431, 2432, 2433, 2434, 2435, 2436, 2437, and 2438, the action at block 2864 can be omitted.

The method can further include adjusting the position of the movable platform at block 2866. The controller 2660 or a local controller can send one or more signals to any one or more of the actuator systems 1920, 2022, and 2024 that can move the platform 1800.

The actuator systems 1920 can affect motion in the Z-direction, θ_{X}, and θ_{Y}. Ideally, as illustrated in FIG. 29, the bonding surfaces of the set of dies 2922 and bonding surfaces within the bonding substrate 2948 are perfectly parallel to each other. In practice, the bonding surfaces of the set of dies 2922 and bonding surfaces within the bonding substrate 2948 may or may not be perfectly parallel to each other. Movement in the Z-direction, θ_{X}, and θ_{Y} can affect the relative positions of bonding surfaces of the set of dies 2922 and the bonding surfaces of the bonding substrate 2948 are within the previously described tolerances for the Z-direction, θ_{X}, and θ_{Y}. The adjustments made for such movements can help reduce the likelihood of causing damage to any die of the set of dies 2922, any bonding site within the bonding substrate 2948, or a combination of any die any die of the set of dies 2922 and the bonding sites within the bonding substrate 2948 due to nonuniform contact when a force is being applied during bonding of any one or more dies within the set of dies 2922, any one or more bonding sites within the bonding substrate 2948, or both any one or more dies within the set of dies 2922, any one or more bonding sites within the bonding substrate 2948.

The actuator systems 2022 and 2024 can affect motion in the X-direction, Y-direction, and θ_{Z}. Movement in the X-direction, Y-direction, and θ_{Z} can affect the relative positions of the bonding pads of the set of dies 2922 and the bonding pads of the bonding substrate 2948 are within the previously described tolerances for the X-direction, Y-direction, and θ_{Z}. The adjustments made for such movements can help achieve good electrical and physical contact and acceptably low contact resistance as compared to not making any adjustment.

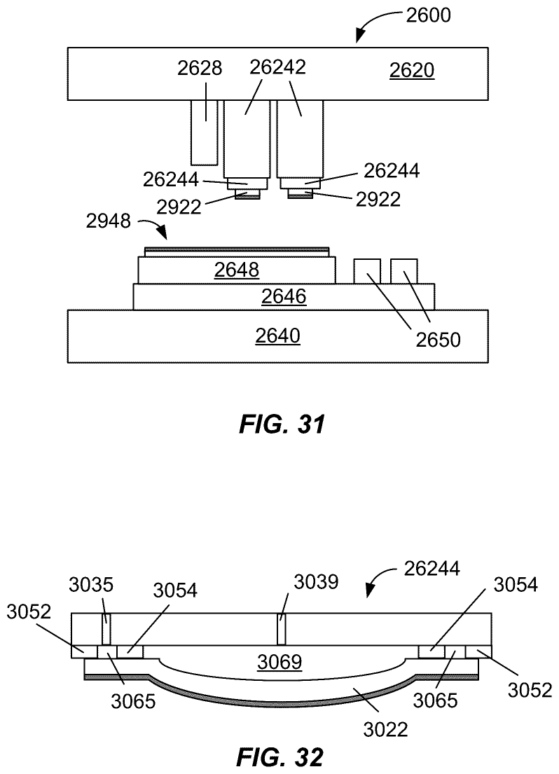

The method can include receiving at a controller signals from registration hardware at block 2868 in FIG. 28. In an implementation, after the adjustment is made to the movable platform 1800, the registration hardware 2650 can obtain information regarding the set of dies 2922. In same or different implementation, the registration hardware 2628 can obtain information regarding the bonding substrate 2948. The method continues as it returns to decision diamond 2842 to determine if all of the dimensional differences are within tolerance. When the dimensional differences between the set of dies 2922 and the bonding substrate 2948 are within tolerance, the set of dies 2922, the bonding substrate 2948, or both are moved such that the set of dies 2922 overlap their corresponding die bonding sites within the bonding substrate 2948 as illustrated in FIG. 31. The process continues at block 2762 in FIG. 27.

The method can further include bowing the set of dies while being held by the array of bonding heads at block 2762 in FIG. 27. Data can be useful in determining how much pressurization should be used to bow the set of dies 2922. For example, as a die occupies a larger area (X-direction and Y-direction dimensions) and is thinner (Z-direction dimension), less pressure is needed to bow the die as compared to a die that occupies a smaller area, is thicker, or both. If the die is attached to a backing plate, the combined thickness of the die and backing plate can be used when determining the pressure to achieve a desired amount of bowing. The data can be obtained for many different die areas and thicknesses. The memory 2662 or a table or database external to the die bonding system 2600 can have data that correlates different areas and thicknesses of the die and the positive pressures or ranges of positive pressures to use to allow for sufficient bowing of the dies.

Referring to FIGS. 26 and 32, the controller 2660 or a local controller can transmit a signal for a pressure actuator to be activated and allow a pressurized gas to increase the pressure within a flow channel 3039 and a zone 3069 that can be defined at least in part by the land 3054. A pressure sensor can sense the pressure within the flow channel 3039 and the zone 3069 and transmit signals to the controller 2660 or the local controller, so that the controller 2660 or the local controller can control the pressure to be at or within acceptable tolerance of a targeted pressure. As the pressure within the zone 3069 increases, the dies bow away die chuck 26244 and toward the base 2640 or the bonding substrate 2948 that is coupled to the base 2640. FIG. 32 illustrates the particular die 3022, and the other dies within the set of dies 2922 can have a bowed shape similar to the particular die 3022 illustrated in FIG. 32.

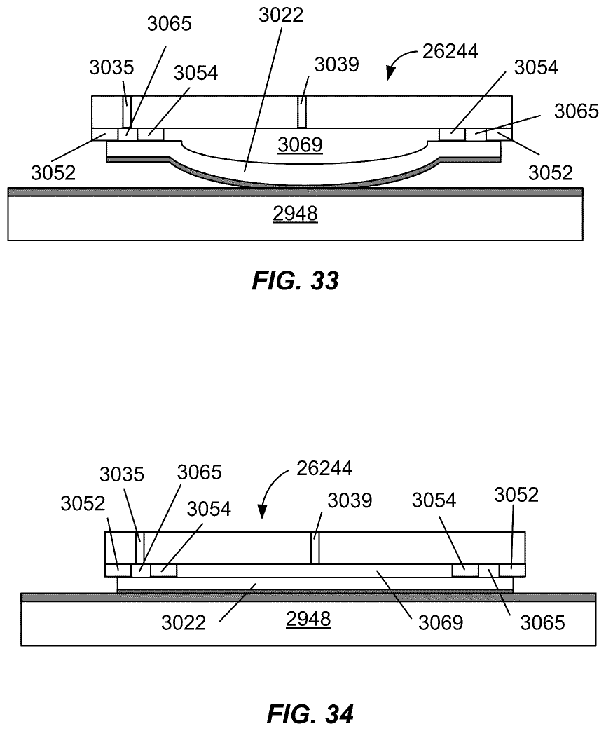

The method can include bringing the set of dies and die bonding sites in contact while the dies are bowed at block 2764 in FIG. 27. Referring to FIGS. 26 and 33, the array of die chucks 26244 within the array of bonding heads 2624 can be extended toward the bonding substrate 2948, the substrate chuck 2648 can be extended toward the array of bonding heads 2624, or both. As illustrated in FIG. 33, the center of the particular die 3022 contacts a die bonding site of the bonding substrate 2948 before other portions of the particular die 3022 contact the die bonding site. Thus, the likelihood of trapped air between the particular die 3022 and bonding substrate 2948 during bonding is substantially less than if bowing was not performed.

The method can further include bonding the set of dies to corresponding die bonding sites of the bonding substrate at block 2766 in FIG. 27. Referring to FIGS. 26 and 34, the die chucks 26244 within the array of bonding heads 2624 can be further extended toward the bonding substrate 2948, the substrate chuck 2648 can be extended toward the array of bonding heads 2624, or both. The amount of bowing can be reduced as contact area between the particular die 3022 and the corresponding die bonding site of the bonding substrate 2948 increases.

Pressure is exerted to bond the set of dies 2922 to corresponding bonding sites of the bonding substrate 2948. In an implementation, the bonds can be oxide-to-oxide bonds. The force during bonding can be at least 5 N, at least 10 N, at least 20 N, at least 50 N or at least 100 N. In an implementation, regarding pressure, the pressure during bonding can be in a range from 0.5 N/cm² to 20 N/cm². The controller 2660 or a local controller can transmit a signal for a motor, hydraulic pressure system, or another mechanical component that can be used to drive the array of bonding heads 2624, the substrate chuck 2648, or both in the Z-direction to achieve the bonding pressure. During bonding, if needed or desired, the pressure within the zone 3069 can be at a positive pressure that is at or within a tolerance of the pressures exerted by the motor, the hydraulic pressure system, or other mechanical component to allow for more uniform pressure along the surface of the set of dies 2922, including the particular die 3022, illustrated in FIG. 34. In another implementation, the pressure within the zone 3069 can be at or near ambient pressure. In the same or different implementation, the pressure within a zone 3065 can remain at vacuum pressure, be at or near ambient pressure, or a pressure that is substantially the same as within the zone 3069.

The bonding can be performed at room temperature (for example, at a temperature in a range from 20° C. to 25° C.) or higher. Bonding is performed at a temperature less than a subsequent anneal to expand conductive metal within the dies and at the die bonding sites. The temperature may be limited depending on films present during bonding or components within the die bonding system 2600. For example, the temperature may be no higher than approximately 200° C. After reading this specification, skilled artisans will be able to determine the pressure and temperature used for bonding.

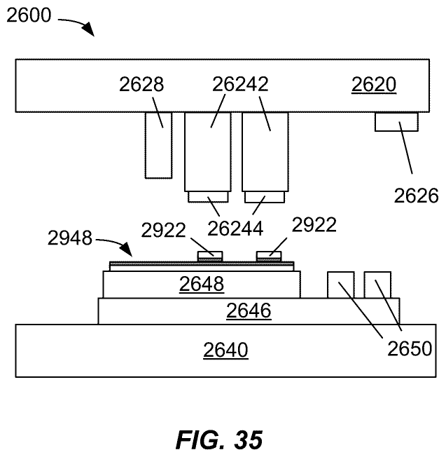

FIG. 35 includes a cross-sectional view of the die bonding system 2600 after the set of dies 2922 are bonded to corresponding die bonding sites of the bonding substrate 2948. At this point in the method, one transfer cycle has been completed. In an implementation, for each die within the set of dies 2922, a maximum X-direction alignment error between the center of the die and the center of its corresponding die bonding site is at most 50 microns. In the same or different implementation, for each die within the set of dies 2922, a maximum Y-direction alignment error between the center of the die and the center of its corresponding die bonding site is at most 50 microns. In any of the foregoing or a different implementation, for each die within the set of dies 2922, a maximum θ_{Z} alignment error between the die and its corresponding die bonding site may be at most 3mrad.

A determination is made whether more dies are to be bonded to the bonding substrate at decision diamond 2768 in FIG. 27. If more dies are to be transferred (“YES” branch), the method continues starting at block 2722 with a next set of dies transferred during another transfer cycle. The method can be iterated as many times as needed for the bonding substrate 2948 to have a desired number of dies. If no more dies are to be transferred (“NO” branch from decision diamond 2768 in FIG. 27), the transfer operation is completed.

A hybrid bonding process can include three steps that include a bonding operation, a first anneal to cause the metal within the dies and at the die bonding sites to expand and contact each other, and an optional second anneal to cause metal atoms to cross the metal-metal interface and reduce contact resistance. The previously described methods correspond to the bonding operation.

After all of the transfer cycles have been performed and the transfer operation is completed, the bonding substrate 2948 and the corresponding bonded dies can be annealed at a temperature in a range from 180° C. to 400° C. In an implementation, annealing may be performed at one or more temperatures. As the temperature of the conductive metal increases, the conductive metal expands. The conductive metal in electrical components within the bonding substrate 2948 contacts the conductive metal in the bonded dies to make a physical and electrical coupling between the conductive materials. If needed or desired, the anneal temperature can be increased further, so that atoms from the conductive metals can cross the interfaces between the electrical components in the bonding substrate 2948 and the bonded dies and reduce contact resistance. In an implementation, the physical and electrical coupling can be a physical and electrical connection. Thus, the bonded dies and the sets of electrical components in the bonding substrate 2948 can allow voltages to be passed and current to flow between the bonded dies and the sets of electrical components. The bonding substrate 2948 can be removed from the die bonding system 2600 or moved to a different portion of the die bonding system 2600 or a different tool to perform the anneal operations.

The method can further include performing one or more post-bonding operations at block 2782 in FIG. 27. Non-limiting examples electrical testing the electronic devices that includes the bonded dies, dicing the bonding substrate into individual electronic devices, cleaning the electronic devices, packaging the electronic devices, or performing another suitable post-bonding operation. The order in which the post-bonding operations may or may not depend on the particular electronic devices. For example, the packaging operation may be performed before or after the dicing operation is performed. Still further, more than one electrical test may be performed at different times where an intervening operation may or may not be performed between the electrical tests. For example, a first electrical test for electrical shorts or electrical opens may be performed before packaging. After packaging, a second electrical test can be performed to test a memory to ensure data can be written and retrieved or a processor to ensure instructions can be performed properly. At this point in the method, electronic devices have been made.

The actuator systems described herein are well suited for a multi-degree of freedom motion mechanism, such as the module 2500 that can be used within a die bonding head of the die bonding system 2600. The actuator systems can allow the die bonding system 2600 to achieve high precision with respect bonding dies to the bonding substrate and achieve high production throughput. In an implementation, the die bonding system can achieve the previously described tolerances in the X-direction, Y-direction, or Z-direction or for θ_{X}, θ_{Y}, or θ_{Z}.

The actuator systems within the die bonding system 2600 are well suited to adjust the positions of the die chucks 26244 within the array of bonding heads 2624 relatively faster as compared to a conventional die bonding system. With respect to the registration and metrology operation, an adjustment cycle can start from a first point in time when signals from the registration hardware 2650 are processed during the current adjustment cycle at the controller 2660 with respect to a current position of the set of dies and ends at a second point in time when adjusting the position of the movable platform 1800 is completed. In an implementation, the adjustment cycle can correspond to blocks 2864 and 2866 in FIG. 28. The die bonding system 2600 can perform the adjustment cycle frequency of at least 50 Hz, at least 200 Hz, at least 500 Hz, or at least 1.1 kHz. In an implementation, the die bonding system 2600 may be able to perform at a adjustment cycle frequency of at most 5 kHz

In an implementation, the arrangement of flexures 742 and 1144 may occupy a relatively smaller space as compared to a conventional actuator system. The flexure 742 includes an opening 844 that allows the flexure 1144 to pass completely through the flexure 742. In a particular implementation, the opening 844 within the flexure 742 can be an open-ended slot that allows for easy insertion of the flexure 1144 within the flexure 742 when the coupling of the flexures 742 and 1144 together.

Note that not all of the activities described above in the general description or the examples are required, that a portion of a specific activity may not be required, and that at least one further activities can be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of systems and apparatuses that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A die bonding system comprising:
a first frame;
a first movable platform adapted to retain a first die chuck;
a first actuator for moving the first movable platform relative to the first frame, wherein the first actuator includes:
a first fixed portion attached to the first frame; and
a first moving portion that is adapted to supply a first force in a first direction relative to the first fixed portion;
a first flexure with a first degree of freedom in the first direction and is connected to the first moving portion of the first actuator and the first frame; and
a second flexure with a plurality of degrees of freedom in directions other than the first direction and is connected to the first moving portion of the first actuator and the first movable platform.

2. The die bonding system of claim 1, wherein:
the first degree of freedom of the first flexure is an only degree of freedom for the first flexure, and
the second flexure has five degrees of freedom.

3. The die bonding system of claim 1, wherein:
the first flexure includes a parallelogram, one double parallelogram, or a plurality of parallelograms, and
the second flexure is a wire flexure.

4. The die bonding system of claim 3, wherein the first flexure includes the one double parallelogram and no other double parallelogram.

5. The die bonding system of claim 3, wherein the wire flexure comprises a midsection, a first end section along a first end of the midsection, and a second end section along a second end of the midsection that is opposite the first end of the midsection, wherein a diameter of the midsection is greater than a diameter of each of the first end section and the second end section.

6. The die bonding system of claim 1, wherein:
the first flexure includes:
a base connected to the first frame;
a first flexure moving portion connected to the first moving portion of the first actuator;
an intermediate body;
a first blade connecting the base to the intermediate body; and
a second blade connecting the first flexure moving portion to the intermediate body; and
the second flexure passes through the first blade and the second blade of the first flexure without touching the first blade or the second blade.

7. The die bonding system of claim 6, wherein the first blade is adapted such that the second flexure passes through a center of compliance of the first flexure.

8. The die bonding system of claim 6, wherein:
the second flexure includes a wire flexure that includes a midsection, a first end section along a first end of the midsection, and a second end section along a second end of the midsection that is opposite the first end of the midsection,
a diameter of the midsection is greater than a diameter of each of the first end section and the second end section, and
the midsection extends through the first blade and the second blade.

9. The die bonding system of claim 1, wherein the second flexure is adapted to be coupled between the first flexure and the first die chuck.

10. The die bonding system of claim 1, wherein the first actuator comprises a voice coil actuator, a piezoelectric actuator, a stepper motor, a servo motor, or a thermal expansion actuator.

11. The die bonding system of claim 1, wherein:
a first die bonding head includes the first movable platform, the first actuator, the first flexure, and the second flexure, and
the die bonding system further comprises a second die bonding head that is substantially identical to the first die bonding head.

12. The die bonding system of claim 1, further comprising:
a second frame;
a second movable platform adapted to retain a second die chuck, wherein the second movable platform is spaced apart from the first movable platform;
a second actuator for moving the second movable platform relative to the second frame, wherein the second actuator includes:
a second fixed portion attached to the second frame; and
a second moving portion that adapted to supply a second force in the first direction relative to the second fixed portion;
a third flexure including a double parallelogram, wherein the double parallelogram is an only double parallelogram of the third flexure, wherein the third flexure is connected to the second moving portion of the second actuator and the second frame; and
a fourth flexure is connected to the third flexure and the second movable platform, wherein the fourth flexure is a wire flexure.

13. The die bonding system of claim 1, further comprising:
a second frame;
a second movable platform adapted to retain a second die chuck, wherein the second movable platform is spaced apart from the first movable platform;
a second actuator for moving the second movable platform relative to the second frame, wherein the second actuator includes:
a second fixed portion attached to the second frame; and
a second moving portion that adapted to supply a second force in the first direction relative to the second fixed portion;
a third flexure including a first blade and a second blade, wherein
the third flexure is connected to the second moving portion of the second actuator and the second frame; and
a fourth flexure extending through the first blade and the second blade of the third flexure without touching the first blade and the second blade and is connected to the third flexure and the second movable platform.

14. A system, comprising:
a first flexure including a double parallelogram and adapted to be connected to a frame, wherein the double parallelogram is an only double parallelogram of the first flexure; and
a second flexure is coupled to the first flexure, wherein the second flexure is a wire flexure.

15. The system of claim 14, further comprising:
an actuator including a moving portion coupled to the first flexure,
wherein the second flexure is adapted to be coupled to a movable object.

16. The system of claim 15, wherein the second flexure is adapted to be coupled between the first flexure and the movable object.

17. The system of claim 14, wherein the first flexure is a guiding flexure, and the second flexure is a decoupling flexure.

18. A system, comprising:
a first flexure including a first blade; and
a second flexure coupled to the first flexure and extending through the first blade without touching the first blade.

19. The system of claim 18, wherein:
the first flexure comprises a plurality of blades including the first blade and a second blade; and
the second flexure extends through the second blade without touching the second blade.

20. The system of claim 18, further comprising:
an actuator including a moving portion coupled to the first flexure,
wherein the second flexure is adapted to be coupled to a movable object.

21. A method of manufacturing a plurality of articles comprising:
bonding a die to a substrate using a die bonding system, wherein the die bonding system includes:
a first frame;
a first movable platform adapted to retain a first die chuck;
a first actuator for moving the first movable platform relative to the first frame, wherein the first actuator includes:
a first fixed portion attached to the first frame; and
a first moving portion that is adapted to supply a first force in a first direction relative to the first fixed portion;
a first flexure with a first degree of freedom in the first direction and is connected to the first moving portion of the first actuator and the first frame; and
a second flexure with a plurality of degrees of freedom in directions other than the first direction and is connected to the first moving portion of the first actuator and the first movable platform; and
processing the substrate to manufacture the plurality of articles.
